(19) United States
(12) Patent Application Publication
(10) Pub. No.: US 2026/0096204 A1
(43) Pub. Date: Apr. 2, 2026

(54) SEMICONDUCTOR DEVICE INCLUDING MULTI-LAYER WORK-FUNCTION METAL

(71) Applicant: SAMSUNG ELECTRONICS CO., LTD., Suwon-si (KR)

(72) Inventors: Hyeok-Jun Son, Latham, NY (US); Junmo Park, Clifton Park, NY (US); Kang-ill Seo, Springfield, VA (US)

(73) Assignee: SAMSUNG ELECTRONICS CO., LTD., Suwon-si (KR)

(21) Appl. No.: 19/264,110

(22) Filed: Jul. 9, 2025

Related U.S. Application Data
(60) Provisional application No. 63/701,964, filed on Oct. 1, 2024.

(51) Int. Cl. H10D 84/85; H10D 84/01

(52) U.S. Cl. CPC H10D 84/856; H10D 84/0177; H10D 84/851

(57) ABSTRACT

Provided is a semiconductor device which may include: a plurality of 1^{st} channel layers; a 1^{st} source/drain region on the plurality of 1^{st} channel layers; and a gate structure including a 1^{st} work-function metal layer on the plurality of 1^{st} channel layers, wherein the 1^{st} work-function metal layer includes a 1^{st} layer between the plurality of 1^{st} channel layers and a 2^{nd} layer on side surfaces of the plurality of 1^{st} channel layers, and atomic percent of a 1^{st} metal in the 1^{st} layer is different from atomic percent of the 1^{st} metal in the 2^{nd} layer.

### CROSS-REFERENCE TO RELATED APPLICATION

This application is based on and claims priority from U.S. Provisional Application No. 63/701,964 filed on Oct. 1, 2024 in the U.S. Patent and Trademark Office, the disclosure of which is incorporated herein in its entirety by reference.

### BACKGROUND

### 1. Filed

Apparatuses consistent with example embodiments of the disclosure relate to a semiconductor device including a gate structure having a multi-layer work-function metal.

### 2. Description of Related Art

A stacked field-effect transistor (FET) device has been introduced in response to increased demand for a semiconductor device having a high device density and performance.

The stacked semiconductor device may include a 1^{st} FET at a 1^{st} level and a 2nd FET at a 2nd level above the 1^{st} level, where each of the two FETs may be a fin field-effect transistor (FinFET), a nanosheet transistor, a forksheet transistor, or any other types of FET. The stacked semiconductor device formed of the FinFETs, nanosheet transistors, or forksheet transistors may also be referred to as a three-dimensional stacked semiconductor device.

The FinFET has one or more fin structures, which are protruded from a substrate, as a channel structure and a gate structure surrounding at least three surfaces of each of the fin structures. The nanosheet transistor is characterized by one or more nanosheet channel layers, which are vertically stacked or arranged on a substrate, as a channel structure and a gate structure surrounding all four surfaces of each of the nanosheet channel layers. The nanosheet transistor is referred to as a gate-all-around (GAA) transistor or a multi-bridge channel field-effect transistor (MBCFET). The forksheet transistor is a combination of two nanosheet transistors with an isolation wall therebetween. In the forksheet transistor, nanosheet channel layers of each nanosheet transistor are formed at each side of the isolation wall and pass through a gate structure in parallel with the isolation wall.

In the meantime, the stacked semiconductor device provides various challenges including manufacturing difficulties, for example, in forming the 1^{st} FET at the 1^{st} level as a low-power operation transistor.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

The disclosure provides a stacked semiconductor device in which a 1^{st} FET may have a two-tier work-function metal layer to achieve a lower-power device and facilitate formation of a work-function metal layer for a 2^{nd} FET above the 1^{st} FET in a process of the stacked semiconductor device.

According to an aspect of the disclosure, there is provided a semiconductor device which may include a plurality of 1^{st} channel layers, a 1^{st} source/drain region on the plurality of 1^{st} channel layers, and a gate structure including a 1^{st} work-function metal layer on the plurality of 1^{st} channel layers. The 1^{st} work-function metal layer may include a 1^{st} layer between the plurality of 1^{st} channel layers and a 2^{nd} layer on side surfaces of the plurality of 1^{st} channel layers, and atomic percent of a 1^{st} metal in the 1^{st} layer may be different from atomic percent of the 1^{st} metal in the 2^{nd} layer.

According to an aspect of the disclosure, there is provided a semiconductor device which may include a 1^{st} channel structure including a plurality of 1^{st} channel layer, a 1^{st} source/drain region on the 1^{st} channel structure, and a gate structure on the 1^{st} channel structure. The gate structure may include a 1^{st} work-function metal layer including a 1^{st} layer between the plurality of 1^{st} channel layers and a 2^{nd} layer on side surfaces of the plurality of 1^{st} channel layers, and the 1^{st} layer and the 2^{nd} layer may have an interface or junction therebetween.

According to an aspect of the disclosure, there is provided a method of manufacturing a semiconductor device, which may include forming a plurality of 1^{st} channel layers and forming a gate structure including a 1^{st} work-function metal layer on the plurality of 1^{st} channel layers. The 1^{st} work-function metal layer may be formed such that the 1^{st} work-function metal layer includes a 1^{st} layer between the plurality of 1^{st} channel layers and a 2^{nd} layer on side surfaces of the plurality of 1^{st} channel layers, and atomic percent of a 1^{st} metal in the 1^{st} layer is different from atomic percent of the 1^{st} metal in the 2^{nd} layer.

According to an aspect of the disclosure, there is provided a method of manufacturing a semiconductor device, which may include forming a plurality of 1^{st} channel layers on a substrate, forming a 1^{st} layer of a 1^{st} work-function metal layer surrounding the plurality of 1^{st} channel layers, removing an outer layer of the 1^{st} layer on side surfaces of the plurality of 1^{st} channel layers, leaving an inner layer of the 1^{st} layer between the plurality of 1^{st} channel layers, and forming a 2^{nd} layer of the 1^{st} work-function metal layer on the side surfaces of the plurality of 1^{st} channel layers.

### BRIEF DESCRIPTION OF DRAWINGS

Example embodiments of the disclosure will be more clearly understood from the following detailed description taken in conjunction with the accompanying drawings.

FIGS. 1A and 1B illustrate a stacked semiconductor device in which a 1^{st} field-effect transistor (FET) at a 1^{st} level and a 2^{nd} FET at a 2^{nd} level have different device widths, according to one or more embodiments.

FIGS. 2A-2H illustrate intermediate semiconductor devices obtained after respective steps of manufacturing a stacked semiconductor device in which a 1^{st} FET at a 1^{st} level and a 2^{nd} FET at a 2^{nd} level have different device widths, according to one or more embodiments.

FIG. 3 illustrates a portion of a non-overlapping region of an intermediate semiconductor device of FIG. 2B in the channel-length direction view, according to one or more embodiments.

FIGS. 4A and 4B illustrate a stacked semiconductor device in which a 1^{st} FET at a 1^{st} level and a 2^{nd} FET at a 2^{nd} level have different device widths and a two-tier work-function metal layer is formed in the 1^{st} FET, according to one or more embodiments.

FIGS. 5A-5J illustrate intermediate semiconductor devices obtained after respective steps of manufacturing a stacked semiconductor device in which a 1^{st} FET at a 1^{st} level and a 2^{nd} FET at a 2^{nd} level have different device widths and a two-tier work-function metal layer is formed in the 1^{st} FET, according to one or more embodiments.

FIGS. 6A and 6B are a flowchart of manufacturing a stacked semiconductor device in which a 1^{st} FET at a 1^{st} level and a 2^{nd} FET at a 2^{nd} level have different device widths and a two-tier work-function metal layer is formed in the 1^{st} FET, according to one or more embodiments.

FIG. 7 is a schematic block diagram illustrating an electronic device including one or more stacked semiconductor devices in which a 1^{st} FET at a 1^{st} level and a 2^{nd} FET at a 2^{nd} level have different device widths and a two-tier work-function metal layer is formed in the 1^{st} FET, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures.

For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented.

It will be understood that, although the terms “1^{st},” “2^{nd}, ” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same”parameters.

It will be understood that, when the term “contact” is used to describe two metal elements, for example, a metal line and a via structure, a barrier metal layer such including titanium (Ti), tantalum (Ta), titanium nitride (TiN), tantalum nitride (TaN), tungsten nitride (WN), nickel nitride (NiN), cobalt nitride (CON), or platinum nitride (PtN), not being limited thereto, may be formed therebetween. Further, it will be understood that, when a metal contract structure is described as being formed on or contact a surface of a source/drain region, a silicide layer including cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” and “insulation” pertains to electrical insulation or separation between structures, layers, components or regions in a corresponding device or structure.

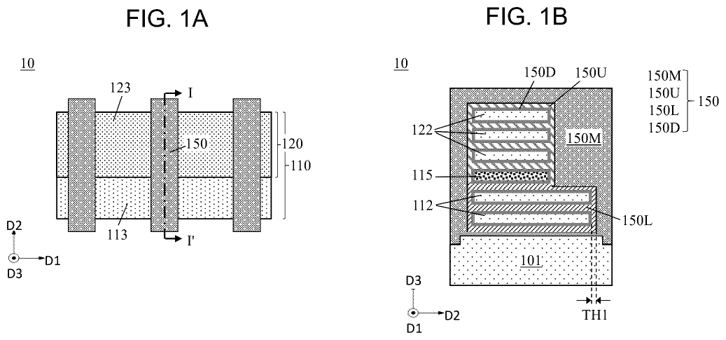

FIGS. 1A and 1B illustrate a stacked semiconductor device in which a 1^{st} field-effect transistor (FET) at a 1^{st} level and a 2^{nd} FET at a 2^{nd} level have different device widths, according to one or more embodiments. FIG. 1A is a plan view of the stacked semiconductor device, and FIG. 1B is a cross-section view of the stacked semiconductor device taken along a line I-I′ shown in FIG. 1A.

It is to be understood that FIGS. 1A and 1B show only selected elements formed on a front side of the stacked semiconductor device such as front-end-of-line (FEOL) structures including channel structures, source/drain regions, and gate structures, and thus, some structural elements such as back-end-of-line (BEOL) and middle-of-line (MOL) structures are not shown for brevity purposes.

Referring to FIGS. 1A and 1B, a stacked semiconductor device 10 may include a 1^{st} active pattern 110 and a 2^{nd} active pattern 120 extending in a D1 direction. The 2^{nd} active pattern 120 may be stacked on the 1^{st} active pattern 110 formed on a substrate 101 in a D3 direction intersecting the D1 direction and a D2 direction, and partially overlap the 1^{st} active pattern 110 in the D3 direction. The 1^{st} active pattern 110 may have a greater width than the 2^{nd} active pattern 120 in the D2 direction. In the stacked semiconductor device 10 may also be formed a plurality of gate structures 150 arranged in the D1 direction and extending in the D2 direction across the active patterns 110 and 120.

The D1 direction refers to a channel-length direction in which a current flows between two source/drain regions connected to each other through a channel structure, the D2 direction is a channel-width direction or a cell-height direction, and the D3 direction is a channel-thickness direction. The D1 direction and the D2 direction may each be referred to as a horizontal direction and the D3 direction may be referred to as a vertical direction.

The stacked semiconductor device 10 may be formed of a 1^{st} FET, which is an n-type field-effect transistor (NFET) at a 1^{st} level or a lower stack, and a 2^{nd} FET, which is a p-type field-effect transistor (PFET) at a 2^{nd} level or an upper stack above the 1^{st} level in the D3 direction. The 1^{st} FET and the 2^{nd} FET may be formed based on the 1^{st} active pattern 110 and the 2^{nd} active pattern 120, respectively, along with a corresponding gate structure 150.

The 1^{st} active pattern 110 for the 1^{st} FET may form a 1^{st} channel structure 112 and 1^{st} source/drain regions 113 at the 1^{st} level. The 1^{st} channel structure 112 may include a plurality of 1^{st} nanosheet layers, as 1^{st} channel layers, epitaxially grown from the substrate 101 therebelow to form the 1^{st} FET as a nanosheet transistor. The substrate 101 may be a silicon (Si) substrate although it may include other materials such as silicon germanium (SiGe), silicon carbide (SiC), not being limited thereto, and the 1^{st} nanosheet layers may also be formed to include silicon (Si).

The 1^{st} source/drain regions 113 may be of n-type epitaxially grown from the 1^{st} nanosheet layers of the 1^{st} channel structure 112 to be formed of silicon (Si) doped with n-type impurities (e.g., phosphorus (P), arsenic (As), or antimony (Sb)). The 1^{st} channel structure 112 may be surrounded by a gate structure 150 which controls current flow between the 1^{st} source/drain regions 113 through the 1^{st} channel structure 112.

The gate structure 150 may include a gate dielectric layer 150D formed on or surrounding the 1^{st} nanosheet layers, a 1^{st} work-function metal layer 150L formed on or surrounding the gate dielectric layer 150D, and a gate-fill metal 150M formed on or surrounding the 1^{st} work-function metal layer 150L. The 1^{st} work-function metal layer 150L and the gate-fill metal 150M may be collectively referred to as a 1^{st} gate electrode. The gate dielectric layer 150D may be configured to electrostatically control channel conductivity while blocking current flow between the 1^{st} gate electrode and the 1^{st} channel structure 112. The 1^{st} work-function metal layer 150L may control a gate threshold voltage of the 1^{st} FET of the stacked semiconductor device 10, and the gate-fill metal 150M may be configured to receive a gate input signal for the stacked semiconductor device 10. The gate structure 150 along with the 1^{st} channel structure 112 and the 1^{st} source/drain regions 113 may form the 1^{st} FET as an NFET at the 1^{st} level.

The 2^{nd} active pattern 120 for the 2^{nd} FET may form a 2^{nd} channel structure 122 and 2^{nd} source/drain regions 123 at the 2^{nd} level. The 2^{nd} channel structure 122 may include a plurality of 2^{nd} nanosheet layers also epitaxially grown from the silicon-based substrate to form the 2^{nd} FET as another nanosheet transistor. The 2^{nd} nanosheet layers may also be formed to include silicon (Si).

The 2^{nd} source/drain regions 123 may be of p-type epitaxially grown from the 2^{nd} nanosheet layers of the 2^{nd} channel structure 122 to be formed of silicon germanium (SiGe) doped with p-type impurities (e.g., boron (B), gallium (Ga), or indium (In)). The 2^{nd} channel structure 122 may also be surrounded by the gate structure 150 which controls current flow between the 2^{nd} source/drain regions 123 through the 2^{nd} channel structure 122.

The gate dielectric layer 150D formed on or surrounding the 1^{st} channel structure 112 may extend to also be formed on or surround the 2^{nd} nanosheet layers, and a 2^{nd} work-function metal layer 150U may be formed on or surround this gate dielectric layer on the 2^{nd} nanosheet layers, and further, the gate-fill metal 150M formed on or surrounding the 1^{st} work-function metal layer 150L may also extend to be formed on or surround the 2^{nd} work-function metal layer 150U. The 2^{nd} work-function metal layer 150U and the gate-fill metal 150M may be collectively referred to as a 2^{nd} gate electrode. The gate dielectric layer 150D may be configured to electrostatically control channel conductivity while blocking current flow between the 2^{nd} gate electrode and the 2^{nd} channel structure 122, and the 2^{nd} work-function metal layer 150U may control a gate threshold voltage of the 2^{nd} FET of the stacked semiconductor device 10. Thus, the 2^{nd} channel structure 122, the 2^{nd} source/drain regions 123 and the gate structure 150 may form the 2^{nd} FET as a PFET at the 2^{nd} level.

The 1^{st} channel structure 112 including the 1^{st} nanosheet layers and the 2^{nd} channel structure 122 including the 2^{nd} nanosheet layers may be isolated from each other through a middle isolation layer 115 which may be formed of an insulation material or a dielectric material such as SiBCN, SiCN, SiOC, SiOCN, Si₃N₄, etc.

As described earlier, the 2^{nd} active pattern 120 has a smaller width than the 1^{st} active pattern 110 in the D2 direction. Accordingly, the 2^{nd} nanosheet layers forming the 2^{nd} channel structure 122 of the 2^{nd} FET may have a smaller width than the 1^{st} nanosheet layers forming the 1^{st} channel structure 112 of the 1^{st} FET in the D2 direction, and the 2^{nd} channel structure 122 may partially overlap the 1^{st} channel structure 112 in the D3 direction.

For example, left side surfaces of the 2^{nd} nanosheet layers may be aligned or coplanar with left side surfaces of the 1^{st} nanosheet layers in the D3 direction, while right side surfaces of the 2^{nd} nanosheet layers are not aligned or coplanar with right side surfaces of the 1^{st} nanosheet layers in the D3 direction. Thus, the 2^{nd} source/drain regions 123 epitaxially grown from the 2^{nd} nanosheet layers may also be formed to have a smaller width than the 1^{st} source/drain regions 113 epitaxially grown from the 1^{st} nanosheet layers in the D2 direction.

Accordingly, a right side surface of the 1^{st} source/drain region 113 may not be overlapped by the 2^{nd} source/drain region 123, while a left side surface of a 1^{st} source/drain region 113 may be overlapped by the 2^{nd} source/drain region 123. This width difference of the source/drain regions may provide a free space above a top surface of the 1^{st} source/drain region 113 which is not vertically overlapped by the 2^{nd} source/drain region 123 so that other circuit elements such as a frontside contact plug may be vertically formed straight through this space to contact at least a portion of the top surface of the 1^{st} source/drain region 113.

The foregoing structural characteristics of the channel structures 112, 122 and the source/drain regions 113, 123 may be provided to address increasing demands for a high device density and an improved device performance in a stacked semiconductor device. As the frontside contact plug can be formed on the top surface of the 1^{st} source/drain region 113 through the non-overlapped free space, the stacked semiconductor device 10 may achieve an area gain and have reduced contact resistance compared to a stacked semiconductor device in which a frontside contact plug is formed on a side surface or a bottom surface of a lower source/drain region (corresponding to the 1^{st} source/drain region 113) when the lower source/drain region and an upper source/drain region (corresponding to the 2^{nd} source/drain region 123) have the same width.

In the stacked semiconductor device 10, the 2^{nd} channel structure 122 forming the 2^{nd} FET may have a greater number of nanosheet layers than that of the 1^{st} channel structure 112 forming the 1^{st} FET such that the two FETs may have the same or substantially same effective channel width (W_{eff}). For example, the 2^{nd} channel structure 122 may have three nanosheet layers while the 1^{st} channel structure 112 have two nanosheet layers.

The different channel widths and the different number of nanosheet layers, that is, channel layers, may facilitate optimization of the stacked semiconductor device 10 in terms of not only area gain for a high-density semiconductor device but also device performance such as current speed, work load distribution, power efficiency, contact resistance, capacitance, thermal control, structural stability, etc.

Referring back to the gate structure 150 of the stacked semiconductor device 10, the gate dielectric layer 150D may include an interfacial layer formed on each of the 1^{st} and 2^{nd} nanosheet layers and a high-k layer formed on the interfacial layer. The interfacial layer may be formed of an oxide material such as silicon oxide (e.g., SiO, SiO₂, etc.) and/or silicon oxynitride (e.g., SiON), not being limited thereto. The high-k layer may be formed of a high-k material such as hafnium (Hf), aluminum (Al), zirconium (Zr), lanthanum (La), magnesium (Mg), barium (Ba), titanium (Ti), lead (Pb), and/or a combination thereof, not being limited thereto. The 1^{st} work-function metal 150L for the 1^{st} FET as NFET may be formed of Al, TiAlC, or TiC and the 2^{nd} work-function metal layer 150U for the 2^{nd} FET as PFET may be formed of TiN or TaN, not being limited thereto. The gate-fill metal 150M may include a metal such as tungsten (W), copper (Cu), aluminum (Al), cobalt (Co), etc., or an alloy thereof, not being limited thereto.

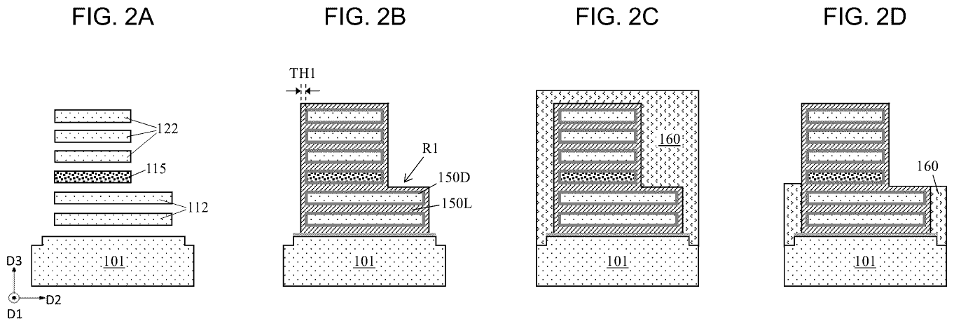

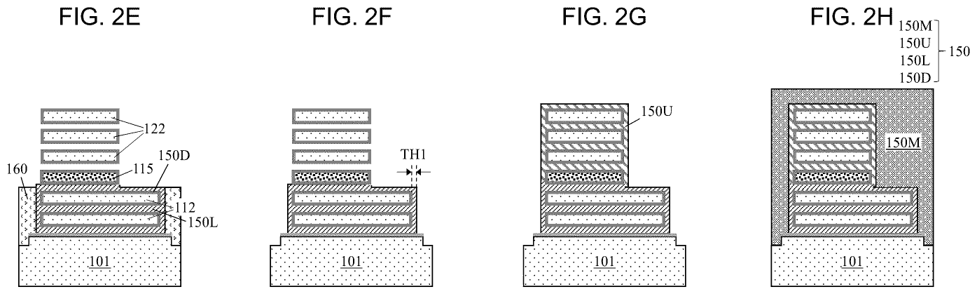

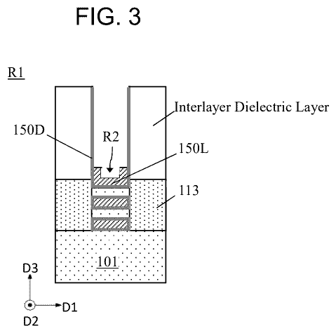

In the meantime, as will be described herebelow in reference to FIGS. 2A-2H and FIG. 3, the 1^{st} work-function metal layer 150L may be formed as a thin layer having a thickness TH1 (e.g., 2.0 nm) at the 1^{st} level considering a subsequent process of forming the 2^{nd} work-function metal layer 150U at the 2^{nd} level. However, in order to form the 1^{st} work-function metal layer 150L to be thin, a certain metal component of the 1^{st} work-function metal layer 150L may not have high atomic percent (at %) which is required to achieve a low-power NFET having a low gate-threshold voltage. For example, in a case where the 1^{st} work-function metal layer 150L is formed of TiAlC, high atomic percent of Al (e.g., 10 at % or higher) may be required to achieve a low-power NFET. In this case, however, forming TiAlC with high atomic percent of Al may require thick layering of TiAlC on the gate dielectric layer 150D subject to a deposition method (e.g., chemical vapor deposition (CVD), atomic layer deposition (ALD), etc.), which would prevent forming a thin 1^{st} work-function metal layer 150L required for the subsequent process of forming the 2^{nd} work-function metal layer 150U. Thus, if the 1^{st} work-function metal layer 150L is formed to have the thin thickness TH1, it may be very difficult to achieve a low-power NFET at the 1^{st} level of the stacked semiconductor device 10.

Provided herebelow is a method of manufacturing the stacked semiconductor device 10 of FIGS. 1A and 1B, according to one or more embodiments.

FIGS. 2A-2H illustrate intermediate semiconductor devices obtained after respective steps of manufacturing a stacked semiconductor device in which a 1^{st} FET at a 1^{st} level and a 2^{nd} FET at a 2^{nd} level have different device widths, according to one or more embodiments.

The stacked semiconductor device manufactured through the steps described herebelow in reference to FIGS. 2A-2H may be the same as the stacked semiconductor device 10 shown in FIGS. 1A and 1B. Thus, duplicate descriptions about functions, materials and structures of the same structural elements may be omitted herebelow and the same reference numerals may be used in FIGS. 2A-2H and the descriptions thereof.

Referring to FIG. 2A, an intermediate semiconductor device including a plurality of 1^{st} channel layers forming a 1^{st} channel structure 112 and a plurality of 2^{nd} channel layers forming a 2^{nd} channel structure 122 may be provided on a substrate 101. Between the 1^{st} channel structure 112 and the 2^{nd} channel structure 122 may be disposed a middle isolation layer 115.

The 1^{st} channel layers of the 1^{st} channel structure 112, the middle isolation layer 115 and the 2^{nd} channel layers of the 2^{nd} channel structure 122 may be formed by removing sacrificial layers formed therebetween and a dummy gate structure surrounding a semiconductor stack which is a previous form of the intermediate semiconductor device shown in FIG. 2A. For example, a semiconductor stack including the 1^{st} channel layers and the 2^{nd} channel layers of silicon (Si) and the sacrificial layers of silicon germanium (SiGe) may have been epitaxially grown based on the substrate 101 including silicon, and the dummy gate structure may have been formed to surround the semiconductor stack through deposition of amorphous silicon or polycrystalline silicon. After a sacrificial layer between a lower stack and an upper stack of the semiconductor stack is removed and replaced by the middle isolation layer 115 through wet or dry etching and deposition of an insulation material or a dielectric material, the semiconductor stack with the dummy gate structure thereon may have been patterned through dry etching such that the upper stack corresponding to the 2^{nd} active pattern 120 of FIG. 1A has a smaller width than the lower stack corresponding to the 1^{st} active pattern 110 of the same FIG. 1A. Further, the other sacrificial layers in the patterned semiconductor stack and the dummy gate structure may have been removed through wet or dry etching to release the 1^{st} channel layers and the 2^{nd} channel layers to form as the 1^{st} channel structure 112 and the 2^{nd} channel structure 122, respectively, with the middle isolation layer 115 therebetween as shown in FIG. 2A.

Referring to FIG. 2B, a gate dielectric layer 150D may be formed on or to surround the channel structures 112, 122 and the middle isolation layer 115, and a 1^{st} work-function metal layer 150L may be formed on or to surround the gate dielectric layer 150D.

The gate dielectric layer 150D may be formed through, for example, atomic layer deposition (ALD) of an interfacial layer including an oxide material and a high-k layer including a high-k material on the channel layers forming both the 1^{st} channel structure 112 and the 2^{nd} channel structure 122 and the middle isolation layer 115. The gate dielectric layer 150D may be formed to surround all four side surfaces of each of the channel layers forming the channel structures 112 and 122 and the middle isolation layer 115. The oxide material for the gate dielectric layer 150D may include silicon oxide (e.g., SiO, SiO₂, etc.) and/or silicon oxynitride (e.g., SiON), not being limited thereto, and the high-k material for the high-k layer may include hafnium (Hf), aluminum (Al), zirconium (Zr), lanthanum (La), magnesium (Mg), barium (Ba), titanium (Ti), lead (Pb), and/or a combination thereof, not being limited thereto.

The 1^{st} work-function metal layer 150L may be formed through, for example, deposition of Al, TiAlC, or TiC by chemical vapor deposition (CVD), plasma-enhanced chemical vapor deposition (PECVD), physical vapor deposition (PVD), ALD, plasma-enhance ALD (PEALD), or a combination thereof. Here, the 1^{st} work-function metal layer 150L may be a thin layer having a thickness TH1 (e.g., 2.0 nm) to facilitate formation of an organic dielectric layer in a next step (FIG. 2C), as will be described later in reference to FIG. 3.

The 1^{st} work-function metal layer 150L may fill in spaces between the channel layers of the channel structure 112 and 122 with the gate dielectric layer 150D thereon. The 1^{st} work-function metal layer 150L may also be formed between the middle isolation layer 115 and the channel layers with the gate dielectric layer 150D thereon and between the lowermost channel layer of the 1^{st} channel structure 112 and the substrate 101 with the gate dielectric layer 150D thereon. The 1^{st} work-function metal layer 150L may also be formed to surround a top surface, a bottom surface and side surfaces of each of the channel layers of the channel structures 112 and 122 with the gate dielectric layer 150D thereon in the channel-width direction view.

Prior to the formation of the 1^{st} work-function metal layer 150L, a high-k protection layer including TiN may be formed on the gate dielectric layer 150D to prevent direct contact between Al and the high-k material, thereby protecting the high-k layer in a case where the 1^{st} work-function metal layer 150L is formed of TiAlC.

Referring to FIG. 2C, an organic dielectric layer 160 may be formed to surround the intermediate semiconductor device obtained in the previous step.

The organic dielectric layer 160 may be formed to surround the channel structures 112, 122 and the middle isolation layer 115 with the gate dielectric layer 150D and the 1^{st} work-function metal layer 150L thereon. The organic dielectric layer 160 may be formed through, for example, PVD, CVD, PECVD, etc. or a combination thereof of polymer such as polyimide to surround the 1^{st} work-function metal layer 150L.

Referring to FIG. 2D, the organic dielectric layer 160 may be patterned to expose at least an upper stack of the intermediate semiconductor device obtained in the previous step.

The organic dielectric layer 160 may be patterned such that the 2^{nd} channel structure 122 with the gate dielectric layer 150D and the 1^{st} work-function metal layer 150L thereon is exposed while the 1^{st} channel structure 112 with the gate dielectric layer 150D and the 1^{st} work-function metal layer 150L thereon is protected by the patterned organic dielectric layer 160. The patterning operation in this step may include wet etching or dry etching such as reactive ion etching, not being limited thereto.

Referring to FIG. 2E, the 1^{st} work-function metal layer 150L may be removed from the exposed upper stack of the intermediate semiconductor device while the 1^{st} work-function metal layer 150L remains in lower stack of the intermediate semiconductor device.

The 1^{st} work-function metal layer 150L surrounding the 2^{nd} channel structure 122 with the gate dielectric layer 150D thereon in the upper stack of the intermediate semiconductor device, hereafter “an upper portion of the 1^{st} work-function metal layer 150L”, may be removed through, for example, dry etching such as chlorine-based plasma etching against the organic dielectric layer 160 protecting the same 1^{st} work-function metal layer 150L surrounding the 1^{st} channel structure 112 with the gate dielectric layer 150D thereon in the lower stack of the intermediate semiconductor device, hereafter “a lower portion of the 1^{st} work-function metal layer 150L.”

Thus, the 2^{nd} channel layers forming the 2^{nd} channel structure 122 may be released from the 1^{st} work-function metal layer 150L with the gate dielectric layer 150D thereon.

Referring to FIG. 2F, the remaining organic dielectric layer 160 surrounding the lower portion of the 1^{st} work-function metal layer 150L is removed from the intermediate semiconductor device.

The removal of the organic dielectric layer 160 formed of polymer may be performed through, for example, wet etching or dry etching such as fluorine-based plasma etching against the 1^{st} work-function metal layer 150L formed of, for example, TiAlC, not being limited thereto.

Referring to FIG. 2G, a 2^{nd} work-function metal layer 150U may be formed on the upper stack of the intermediate semiconductor device obtained in the previous step.

The 2^{nd} work-function metal layer 150U may be formed through, for example, deposition of TiN or TaN by CVD, PECVD, PVD, ALD, PEALD, or a combination thereof. The 2^{nd} work-function metal layer 150U may be formed to fill in spaces between the 2^{nd} channel layers of the 2^{nd} channel structure 122 with the gate dielectric layer 150D thereon and between the middle isolation layer 115 and the lowermost 2^{nd} channel layer. The 2^{nd} work-function metal layer 150U may also be formed to surround a top surface, a bottom surface and side surfaces of each of the 2^{nd} channel layers in the channel-width direction view.

Referring to FIG. 2H, a gate-fill metal 150M may be formed on the 1^{st} work-function metal layer 150L and the 2^{nd} work-function metal layer 150U to finish formation of a gate structure 150.

The gate-fill metal 150M may be formed through, for example, deposition of a metal such as tungsten (W), copper (Cu), aluminum (Al), cobalt (Co), etc., or an alloy thereof, by CVD, PECVD, PVD, ALD, PEALD, or a combination thereof. not being limited thereto.

Prior to the formation of the gate-fill metal 150M on the work-function metal layers 150L and 150U, an oxidation protection layer including TiN may be formed on the work-function metal layers 150L and 150U to prevent oxidation of Al in a case where the 1^{st} work-function metal layer 150L is formed of TiAlC.

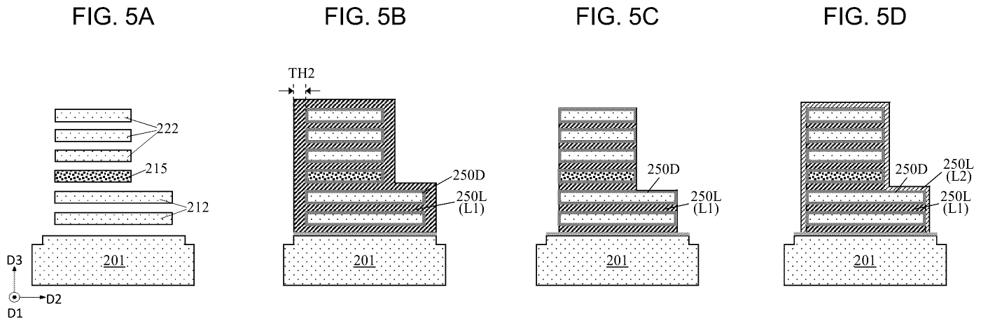

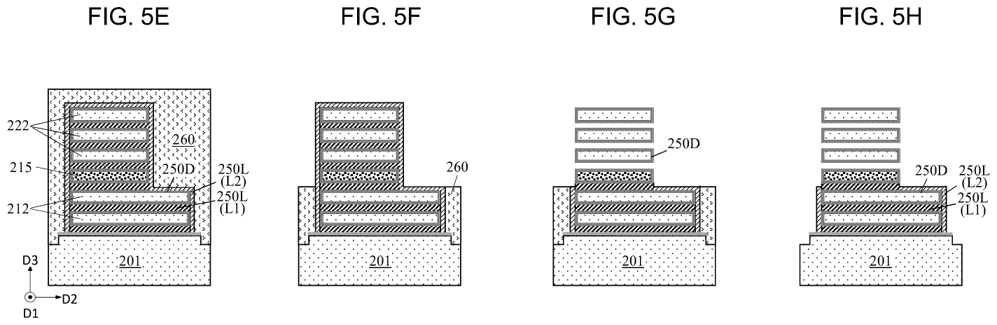

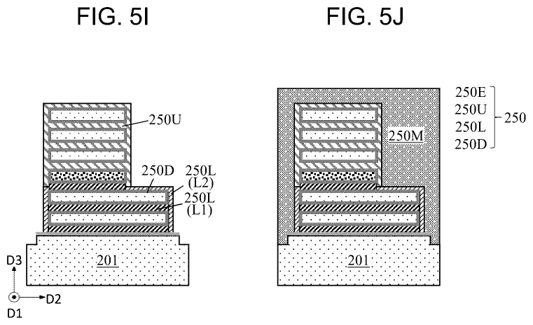

Here, referring back to FIG. 2B in which a non-overlapping region R1 (where the 1^{st} channel structure 112 is not vertically overlapped by the 2^{nd} channel structure 122) is formed and FIG. 3 showing a portion of the non-overlapping region R1 in the channel-length direction view, the 1^{st} work-function metal layer 150L is formed to be thin enough (e.g., the thickness TH1) so that a region R2 can be formed to accommodate therein the organic dielectric layer 160 to protect the lower portion of the 1^{st} work-function metal layer 150L in a process of forming the 2^{nd} work-function metal layer 150U. If, however, the 1^{st} work-function metal layer 150L is formed to be thicker (e.g., greater than the thickness TH1), the region R2 cannot be formed to accommodate therein the organic dielectric layer 160 to protect the lower portion of the 1^{st} work-function metal layer 150L. Then, the dry etching performed in the step of FIG. 5E to remove the upper portion of the 1^{st} work-function metal layer 150L may also attack the lower portion of the 1^{st} work-function metal layer 150L which should remain as a gate structure for a 1^{st} FET of a stacked semiconductor device.

However, as the 1^{st} work-function metal layer 150L is formed to be thin for the purpose of facilitating the formation of the organic dielectric layer 160 in the region R2, atomic percent (at %) of a metal component such as Al may become lower, in which case a gate threshold voltage becomes higher. Thus, the 1^{st} FET of the stacked semiconductor device to be formed as NFET from the above-described intermediate semiconductor device may not achieve a low-power device that can be operational at a low gate threshold voltage.

The following embodiments may address the above contradiction occurring in manufacturing of a stacked semiconductor device in which a 1^{st} FET at the 1^{st} level is formed as NFET when the 1^{st} FET and a 2^{nd} FET at a 2^{nd} level have different device widths.

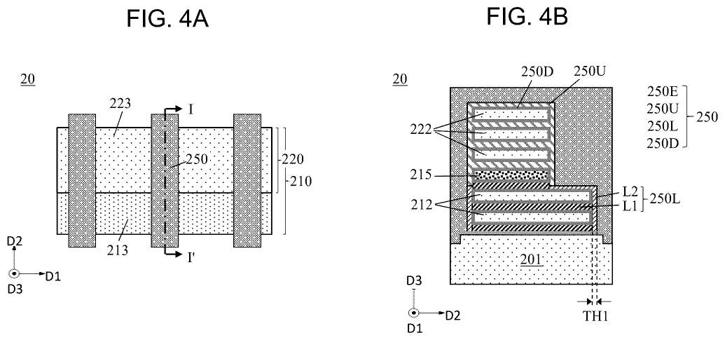

FIGS. 4A and 4B illustrate a stacked semiconductor device in which a 1^{st} FET at a 1^{st} level and a 2^{nd} FET at a 2^{nd} level have different device widths and a two-tier work-function metal layer is formed in the 1^{st} FET, according to one or more embodiments. FIG. 4A is a plan view of the stacked semiconductor device, and FIG. 4B is a cross-section view of the stacked semiconductor device taken along a line I-I′ shown in FIG. 1A.

Referring to FIGS. 4A and 4B, which correspond to FIGS. 1A and 1D, respectively, a stacked semiconductor device 20 may be formed of the same structural elements forming the stacked semiconductor device 10, and thus, duplicate descriptions thereof may be omitted herein. For example, a substrate 201, a 1^{st} active pattern 210 including a 1^{st} channel structure 212 and 1^{st} source/drain regions 213, a 2^{nd} active pattern 220 including a 2^{nd} channel structure 222 and 2^{nd} source/drain regions 223, a middle isolation layer 215, and gate structures 250 of the stacked semiconductor device 20 may be the same as corresponding structural elements of the stacked semiconductor device 10 of FIGS. 1A-1D. Further, the gate structure 250 of the stacked semiconductor device 20 may include a gate dielectric layer 250D, a 1^{st} work-function metal layer 250L of n-type, a 2^{nd} work-function metal layer 250U of p-type, and a gate-fill metal 250M which may be the same as or similar to corresponding structural elements of the stacked semiconductor device 10.

However, unlike the 1^{st} work-function metal layer 150L of the stacked semiconductor device 10, the 1^{st} work-function metal layer 250L of the stacked semiconductor device 20 may be a two-tier work-function metal layer having a two-layer structure. For example, the 1^{st} work-function metal layer 250L of n-type may be formed of a 1^{st} layer L1 and a 2^{nd} layer L2 formed at two different steps. Thus, even if the 1^{st} layer L1 and the 2^{nd} layer L2 are formed of the same material, a connection surface, an interface or a junction may be formed between the two layers L1 and L2 when viewed through, for example, scanning electron microscopy (SEM) or transmission electron microscopy (TEM).

The 1^{st} layer L1 may be formed between the 1^{st} channel layers with the gate dielectric layer 250D thereon. The 1^{st} layer L1 may also be formed between the lowermost 1^{st} channel layer and the substrate 201 with the gate dielectric layer 250D thereon and between the uppermost 1^{st} channel layer and the middle isolation layer 215 with the gate dielectric layer 250D thereon. The 2^{nd} layer L2 may be formed at side surface of the 1^{st} channel layers with the gate dielectric layer 250D thereon and a top surface of the uppermost 1^{st} channel layer with the gate dielectric layer 250D thereon in a non-overlapping region where the 1^{st} channel structure 212 is not vertically overlapped by the 2^{nd} channel structure 222. The 2^{nd} layer L2 may have the same thickness TH1 (e.g., 2.0 nm) of the 1^{st} work-function metal layer 150L of the stacked semiconductor device 10.

Further, the 1^{st} layer L1 and the 2^{nd} layer L2 may have different atomic percent (at %) values of a same metal component. For example, in a case where the 1^{st} work-function metal layer 250L is formed of TiAlC, an atomic percent of Al in the 1^{st} layer L1 may be greater than that in the 2^{nd} layer L2. For example, the atomic percent of Al in the 1^{st} layer L1 may be greater than 10 at % and the atomic percent of Al in the 2^{nd} layer L2 may be smaller than 10 at %.

Thus, while the higher atomic percent of Al in the 1^{st} layer L1 may enable reduction of a gate threshold voltage for a 1^{st} FET of the stacked semiconductor device 20 as NFET at a 1^{st} level, the thin 2^{nd} layer L2 having the thickness TH1 may allow formation of an organic dielectric layer to protect the 1^{st} work-function metal layer 250L in a process or forming the 2^{nd} work-function metal layer 250U.

In the meantime, like the 2^{nd} work-function metal layer 150U of the stacked semiconductor device 10, the 2^{nd} work-function metal layer 250U of the stacked semiconductor device 20 may be a single layer having consistent or uniform atomic percent of metal components. In a case wherein the 2^{nd} work-function metal layer 250U is formed of TaN, atomic percent of Ta may be consistent or uniform throughout the entire 2^{nd} work-function metal layer 250U.

In addition, the thickness TH1 of the 2^{nd} layer L2 may be smaller than a thickness of the 1^{st} layer TH1 remaining between the 1^{st} channel layers, between the lowermost 1^{st} channel layer and the substrate 201.

Provided herebelow is a method of manufacturing the stacked semiconductor device 20 of FIGS. 4A and 4B, according to one or more embodiments.

FIGS. 5A-5J illustrate intermediate semiconductor devices obtained after respective steps of manufacturing a stacked semiconductor device in which a 1^{st} FET at a 1^{st} level and a 2^{nd} FET at a 2^{nd} level have different device widths and a two-tier work-function metal layer is formed in the 1^{st} FET, according to one or more embodiments.

The stacked semiconductor device manufactured through the steps described herebelow in reference to FIGS. 5A-5J may be the same as the stacked semiconductor device 20 shown in FIGS. 4A and 4B. Thus, duplicate descriptions about functions, materials and structures of the same structural elements may be omitted herebelow and the same reference numerals may be used in FIGS. 5A-5J and the descriptions thereof.

Referring to FIG. 5A, an intermediate semiconductor device including a plurality of 1^{st} channel layers forming a 1^{st} channel structure 212 and a plurality of 2^{nd} channel layers forming a 2^{nd} channel structure 222 may be provided on a substrate 201. Between the 1^{st} channel structure 212 and the 2^{nd} channel structure 222 may be disposed a middle isolation layer 215.

The intermediate semiconductor device provided in this step may be the same as the intermediate semiconductor device provided in the step of FIG. 2A, and thus, duplicate descriptions thereof may be omitted herein.

Referring to FIG. 5B, a gate dielectric layer 250D may be formed on or to surround the channel structures 212, 222 and the middle isolation layer 215, and a thick 1^{st} work-function metal layer 250L may be formed on or to surround the gate dielectric layer 250D.

The gate dielectric layer 250D may be formed in the same manner as the gate dielectric layer 150D described in reference to FIG. 2B, and thus, duplicate descriptions thereof may be omitted herein.

Like the 1^{st} work-function metal layer 150L for the stacked semiconductor device 10, the 1^{st} work-function metal layer 250L may be formed through, for example, deposition of Al, TiAlC, or TiC by CVD, PECVD, PVD, ALD, PEALD, or a combination thereof. However, unlike the thin 1^{st} work-function metal layer 150L for the stacked semiconductor device 10, the 1^{st} work-function metal layer 250L may be a thick layer having a greater thickness TH2 (e.g., 3.5 nm) and a higher atomic percent (e.g., 10 at % or higher) of Al in a case where the 1^{st} work-function metal layer 250L is formed of TiAlC.

Still, however, the 1^{st} work-function metal layer 250L may be formed to fill in spaces between the channel layers of the channel structure 212 and 222 with the gate dielectric layer 250D thereon. The 1^{st} work-function metal layer 250L may also be formed between the middle isolation layer 215 and the channel layers with the gate dielectric layer 250D thereon, and between the lowermost channel layer of the 1^{st} channel structure 212 and the substrate 201 with the gate dielectric layer 250D thereon. The 1^{st} work-function metal layer 250L may also be formed to surround a top surface, a bottom surface and side surfaces of each of the channel layers of the channel structures 212 and 222 with the gate dielectric layer 250D thereon in the channel-width direction view.

Prior to the formation of the 1^{st} work-function metal layer 250L, a high-k protection layer including TiN may be formed on the gate dielectric layer 250D to prevent direct contact between Al and the high-k material, thereby protecting the high-k layer in a case where the 1^{st} work-function metal layer 250L is formed of TiAlC.

Referring to FIG. 5C, an outer layer of the 1^{st} work-function metal layer 250L may be removed leaving only an inner layer of the 1^{st} work-function metal layer 250L as a 1^{st} layer L1.

The removal of the outer layer of the 1^{st} work-function metal layer 250L may be performed through, for example, dry or wet etching, after which the inner layer of the 1^{st} work-function metal layer 250L may remain as the 1^{st} layer L1 having a higher atomic percent of Al that may enable implementation of a low gate threshold voltage for the 1^{st} FET as NFET of the stacked semiconductor device to be manufactured from the intermediate semiconductor device. Here, the 1^{st} layer L1 may include portions of the 1^{st} work-function metal layer 250L between the channel layers of the channel structure 212 and 222 with the gate dielectric layer 250D thereon, between the middle isolation layer 215 and these channel layers with the gate dielectric layer 250D therein, and between the lowermost channel layer of the 1^{st} channel structure 212 and the substrate 201 with the gate dielectric layer 250D thereon.

Referring to FIG. 5D, a thin 2^{nd} layer L2 to form the 1^{st} work-function metal layer 250L along with the 1^{st} layer L1 may be formed to surround an outer profile of the intermediate semiconductor device obtained in the previous step, thereby forming a two-tier 1^{st} work-function metal layer 250L.

The 2^{nd} layer L2 may be formed on a top surface of the uppermost channel layer of the 2^{nd} channel structure 222 with the gate dielectric layer 250D thereon and a top surface of the uppermost channel layers of the 1^{st} channel structure 212 in the non-overlapping region where the 1^{st} channel structure 212 is not vertically overlapped by the 2^{nd} channel structure 222. Further, the 2^{nd} layer L2 may be formed on side surfaces of the 1^{st} layer L1 and side surfaces of the channel layers of the channel structures 212 and 222 and the middle isolation layer 215 with the gate dielectric layer 250D thereon.

Here, the 2^{nd} layer L2 may be a thin layer having a thickness TH1 (e.g., 2.0 nm or less) and a lower atomic percent of Al to facilitate formation of an organic dielectric layer in a next step (FIG. 5E).

Prior to the formation of the thin 2^{nd} layer L2, an oxidation protection layer including TiN may be formed on the 1^{st} work-function metal layers 250L to prevent oxidation of Al in a case where the 1^{st} work-function metal layer 250L is formed of TiAlC.

Referring to FIG. 5E, an organic dielectric layer 260 may be formed to surround the intermediate semiconductor device obtained in the previous step.

The organic dielectric layer 260 may be formed to surround the channel structures 212, 222 and the middle isolation layer 215 with the gate dielectric layer 250D and the 1^{st} work-function metal layer 250L (L1 and L2) thereon. The organic dielectric layer 260 may be formed through, for example, PVD, CVD, PECVD, etc. or a combination thereof of polymer such as polyimide to surround the 1^{st} work-function metal layer 250L.

Referring to FIG. 5F, the organic dielectric layer 260 may be patterned to expose at least an upper stack of the intermediate semiconductor device obtained in the previous step while the organic dielectric layer 260 remains in a lower stack of the intermediate semiconductor device to surround and protect a lower stack of the intermediate semiconductor device.

The organic dielectric layer 260 may be patterned such that the 2^{nd} channel structure 222 with the gate dielectric layer 250D and the 1^{st} work-function metal layer 250L (L1 and L2) thereon is exposed while the 1^{st} channel structure 212 with the gate dielectric layer 250D and the 1^{st} work-function metal layer 250L (L1 and L2) thereon is protected by the patterned organic dielectric layer 260. The patterning operation in this step may include dry etching such as reactive ion etching, not being limited thereto.

Referring to FIG. 5G, the 1^{st} work-function metal layer 250L (L1 and L2) may be removed from the exposed upper stack of the intermediate semiconductor device while the 1^{st} work-function metal layer 250L (L1 and L2) remains in a lower stack of the intermediate semiconductor device.

The 2^{nd} work-function metal layer 250L (L1 and L2) surrounding the 2^{nd} channel structure 122 with the gate dielectric layer 250D thereon in the upper stack of the intermediate semiconductor device, hereafter “an upper portion of the 1^{st} work-function metal layer 250L (L1 and L2)”, may be removed through, for example, dry etching such as chlorine-based plasma etching against at least the organic dielectric layer 260 protecting the same 1^{st} work-function metal layer 250L (L1 and L2) surrounding the 1^{st} channel structure 212 with the gate dielectric layer 250D thereon in the lower stack of the intermediate semiconductor device, hereafter “a lower portion of the 1^{st} work-function metal layer 250L.”

Thus, the 2^{nd} channel layers forming the 2^{nd} channel structure 222 may be released from the 1^{st} work-function metal layer 250L with the gate dielectric layer 250D thereon.

Referring to FIG. 5H, the remaining organic dielectric layer 260 surrounding the lower portion of the 1^{st} work-function metal layer 250L may be removed from the intermediate semiconductor device.

The removal of the organic dielectric layer 260 formed of polymer may be performed through, for example, dry or wet etching such as fluorine-based plasma etching against the 1^{st} work-function metal layer 250L (L1 and L2) with the gate dielectric layer 250D thereon.

Referring to FIG. 5I, a 2^{nd} work-function metal layer 250U may be formed on the upper stack of the intermediate semiconductor device obtained in the previous step.

The 2^{nd} work-function metal layer 250U may be formed in the same manner as the 2^{nd} work-function metal layer 150U as described in reference to FIG. 2G, and thus, duplicate descriptions thereof may be omitted herein.

Here, while the 1^{st} work-function metal layer 250L may be a two-tier layer formed of the 1^{st} layer L1 having a higher atomic percent of Al and the 2^{nd} layer L2 having a lower atomic percent of Al, the 2^{nd} work-function metal layer 250U may be a single layer having consistent or uniform atomic percent of each metal component. In a case wherein the 2^{nd} work-function metal layer 250U is formed of TaN, atomic percent of Ta may be consistent and uniform throughout the entire 2^{nd} work-function metal layer 250U. For example, a portion of the 2^{nd} work-function metal layer 250U on side surfaces of the 2^{nd} channel layers and another portion of the 2^{nd} work-function metal layer 250U between the 2^{nd} channel layers may have the same atomic percent of a metal such as Ta.

Referring to FIG. 5J, a gate-fill metal 250M may be formed on the 1^{st} work-function metal layer 250L (L1 and L2) and the 2^{nd} work-function metal layer 250U to finish formation of a gate structure 250.

The gate-fill metal 250M may be formed in the same manner as the gate-fill metal 150M as described in reference to FIG. 2H, and thus, duplicate descriptions thereof may be omitted herein.

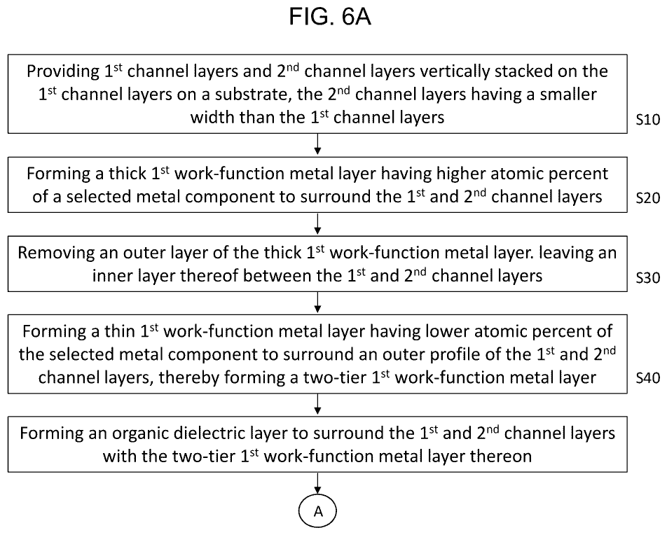

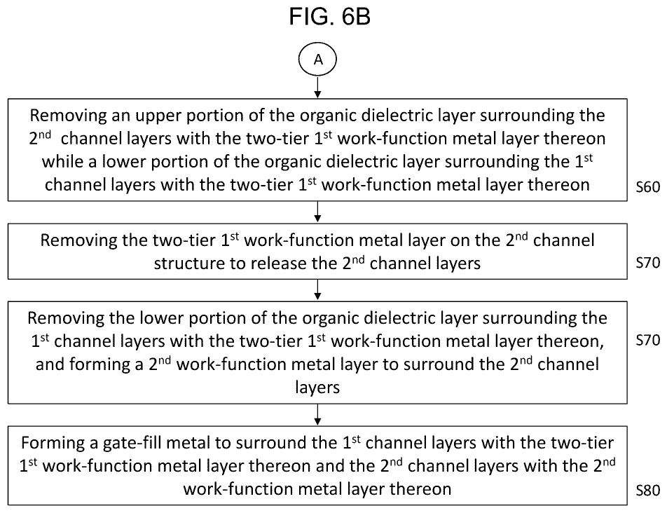

FIGS. 6A and 6B are a flowchart of manufacturing a stacked semiconductor device in which a 1^{st} FET at a 1^{st} level and a 2^{nd} FET at a 2^{nd} level have different device widths and a two-tier work-function metal layer is formed in the 1^{st} FET, according to one or more embodiments.

The stacked semiconductor device to be formed through the flowchart of FIGS. 6A and 6B may be the same or similar to the stacked semiconductor device 20 manufactured through steps described above in reference to FIGS. 5A-5J, and thus, duplicate descriptions thereof may be omitted herein.

In step S10, an intermediate semiconductor device including a 1^{st} channel structure of 1^{st} channel layers and a 2^{nd} channel structure of 2^{nd} channel layers vertically stacked on the 1^{st} channel structure may be provided on a substrate, the 2^{nd} channel structure having a smaller width than the 1^{st} channel structure in the D2 direction.

The intermediate semiconductor device in this step may be formed from a semiconductor stack including a plurality of channel layers and sacrificial layers alternatingly stacked on the substrate based on a dummy gate structure surrounding the semiconductor stack as described in reference to FIG. 5A. Between the 1^{st} channel structure and the 2^{nd} channel structure a middle isolation layer may be formed to isolate the two channel structures.

In step S20, a thick 1^{st} work-function metal layer having higher atomic percent of a selected metal component may be formed to surround the 1^{st} channel layers and the 2^{nd} channel layers.

The thick 1^{st} work-function metal layer may be formed of TiAlC, and the selected metal component of the thick 1^{st} work-function metal layer may be Al of which atomic percent is, for example, 10% or higher, in the thick 1^{st} work-function metal layer. Here, the thickness of the thick 1^{st} work-function metal layer may be, for example, 3.5 nm.

In step S30, an outer layer of the thick 1^{st} work-function metal layer may be removed leaving an inner layer of the thick 1^{st} work-function metal layer between the 1^{st} channel layers and between the 2^{nd} channel layers in the D3 direction (vertical direction).

The inner layer of the thick 1^{st} work-function metal layer may also remain between the lowermost 1^{st} channel layer and the substrate and between the middle isolation layer and the 1^{st} and 2^{nd} channel layers.

In step S40, a thin 1^{st} work-function metal layer having lower atomic percent of the selected metal component may be formed to surround an outer profile of the 1^{st} channel layers and the 2^{nd} channel layers, thereby forming a two-tier 1^{st} work-function metal layer.

The thin 1^{st} work-function metal layer may also be formed of TiAlC, and atomic percent of the selected metal component, that is, Al may be 10% or lower in the thin 1^{st} work-function metal layer. Here, the thickness of the thin 1^{st} work-function metal layer may be, for example, 2.0 nm.

In step S50, an organic dielectric layer may be formed to surround the 1^{st} channel structure and the 2^{nd} channel structure with the two-tier 1^{st} work-function metal layer thereon.

In step S60, an upper portion of the organic dielectric layer surrounding the 2^{nd} channel structure with the two-tier 1^{st} work-function metal layer thereon may be removed while a lower portion of the organic dielectric layer surrounds and protects the 1^{st} channel structure with the two-tier 1^{st} work-function metal layer thereon.

In step S70, the two-tier 1^{st} work-function metal layer on the 2^{nd} channel structure may be removed to release the 2^{nd} channel layers of the 2^{nd} channel structure.

In step S80, the lower portion of the organic dielectric layer surrounding the 1^{st} channel structure with the two-tier 1^{st} work-function metal layer thereon may be removed, and a 2^{nd} work-function metal layer may be formed to surround the 2^{nd} channel layers.

Here, the 2^{nd} work-function metal layer may be a single layer having consistent or uniform atomic percent of each metal component.

In step S90, a gate-fill metal may be formed to surround the 1^{st} channel structure with the two-tier 1^{st} work-function metal layer thereon and the 2^{nd} channel structure with the 2^{nd} work-function metal layer thereon.

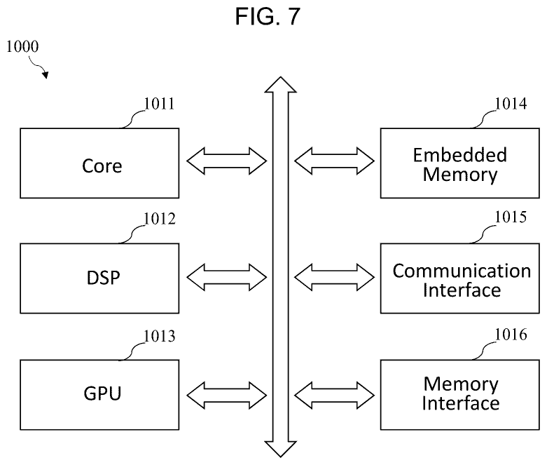

FIG. 7 is a schematic block diagram illustrating an electronic device including one or more stacked semiconductor devices in which a 1^{st} FET at a 1^{st} level and a 2^{nd} FET at a 2^{nd} level have different device widths and a two-tier work-function metal layer is formed in the 1^{st} FET, according to one or more embodiments. These stacked semiconductor devices may include one or more of the stacked semiconductor devices 10 and 20 shown in FIGS. 2A-2B and 4A-4B, respectively.

Referring to FIG. 7, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1017.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include one or more of the stacked semiconductor devices 10 and 20 shown in FIGS. 2A-2B and 4A-4B, respectively.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
a plurality of 1^{st} channel layers;
a 1^{st} source/drain region on the plurality of 1^{st} channel layers; and
a gate structure comprising a 1^{st} work-function metal layer on the plurality of 1^{st} channel layers,
wherein the 1^{st} work-function metal layer comprises a 1^{st} layer between the plurality of 1^{st} channel layers and a 2^{nd} layer on side surfaces of the plurality of 1^{st} channel layers, and
wherein atomic percent of a 1^{st} metal in the 1^{st} layer is different from atomic percent of the 1^{st} metal in the 2^{nd} layer.

2. The semiconductor device of claim 1, wherein the 1^{st} metal is aluminum (Al).

3. The semiconductor device of claim 2, wherein the atomic percent of the 1^{st} metal in the 1^{st} layer is higher than the atomic percent of the 1^{st} metal in the 2^{nd} layer.

4. The semiconductor device of claim 3, wherein the 1^{st} layer and the 2^{nd} layer both comprise TiAlC.

5. The semiconductor device of claim 4, wherein the 1^{st} source/drain region is of n-type.

6. The semiconductor device of claim 1, wherein the 1^{st} layer has a greater thickness than the 2^{nd} layer.

7. The semiconductor device of claim 1, wherein the 1^{st} work-function metal layer is of n-type.

8. The semiconductor device of claim 1, further comprising:
a plurality of 2^{nd} channel layers vertically above the plurality of 1^{st} channel layers; and
a 2^{nd} source/drain region on the plurality of 2^{nd} channel layers,
wherein the gate structure further comprises a 2^{nd} work-function metal layer between the plurality of 2^{nd} channel layers and on side surfaces of the plurality of 2^{nd} channel layers, and
wherein the 2^{nd} work-function metal layer has uniform atomic percent of a 2^{nd} metal.

9. The semiconductor device of claim 8, wherein the 2^{nd} metal comprises a titanium (Ti) or tantalum (Ta).

10. The semiconductor device of claim 9, wherein the 2^{nd} source/drain region is of p-type.

11. The semiconductor device of claim 8, wherein the plurality of 1^{st} channel layers have a greater width than the plurality of 2^{nd} channel layers.

12. The semiconductor device of claim 8, wherein the 2^{nd} source/drain region is of p-type.

13. A semiconductor device comprising:
a 1^{st} channel structure comprising a plurality of 1^{st} channel layer;
a 1^{st} source/drain region on the 1^{st} channel structure; and
a gate structure on the 1^{st} channel structure,
wherein the gate structure comprises a 1^{st} work-function metal layer comprising a 1^{st} layer between the plurality of 1^{st} channel layers and a 2^{nd} layer on side surfaces of the plurality of 1^{st} channel layers, and
wherein the 1^{st} layer and the 2^{nd} layer have an interface or junction therebetween.

14. The semiconductor device of claim 13, wherein the 1^{st} layer and the 2^{nd} layer both comprise a 1^{st} metal, and
wherein atomic percent of the 1^{st} metal in the 1^{st} layer is different from atomic percent of the 1^{st} metal in the 2^{nd} layer.

15. The semiconductor device of claim 14, wherein atomic percent of the 1^{st} metal in the 1^{st} layer is higher than atomic percent of the 1^{st} metal in the 2^{nd} layer.

16. The semiconductor device of-claim claim 14, wherein the 1^{st} layer and the 2^{nd} layer both comprise TiAlC, and the 1^{st} metal is Al.

17. A method of manufacture a semiconductor device, the method comprising:
forming a plurality of 1^{st} channel layers; and
forming a gate structure comprising a 1^{st} work-function metal layer on the plurality of 1^{st} channel layers,
wherein the 1^{st} work-function metal layer is formed such that:
the 1^{st} work-function metal layer comprises a 1^{st} layer between the plurality of 1^{st} channel layers and a 2^{nd} layer on side surfaces of the plurality of 1^{st} channel layers, and
atomic percent of a 1^{st} metal in the 1^{st} layer is different from atomic percent of the 1^{st} metal in the 2^{nd} layer.

18. The method of claim 17, wherein the 1^{st} metal is aluminum (Al).

19. The method of claim 18, wherein the atomic percent of the 1^{st} metal in the 1^{st} layer is higher than the atomic percent of the 1^{st} metal in the 2^{nd} layer.

20. The method of claim 19, wherein the 1^{st} layer and the 2^{nd} layer both comprise TiAlC.

21-24. (canceled)
